(19) United States
(12) Patent Application Publication
(10) Pub. No.: US 2012/0326292 A1
(43) Pub. Date: Dec. 27, 2012

(54) ELECTRONIC CONTROL UNIT

(75) Inventors: Yutaka OHASHI, Handa-city (JP); Mitsuhiro Saitou, Obu-city (JP); Yuta Uozaki, Chita-gun (JP)

(73) Assignee: Denso Corporation, Kariya-city (JP)

(21) Appl. No.: 13/524,149

(22) Filed: Jun. 15, 2012

(30) Foreign Application Priority Data
Jun. 22, 2011 (JP) 2011-138247

(51) Int. Cl. H01L 23/34

(52) U.S. Cl. 257/690; 257/E23.08

(57) ABSTRACT

An electronic control unit includes a substrate, a semiconductor module, a heat storage body, an insulator, and a heat sink. The substrate includes a wiring and a land. The semiconductor module includes a semiconductor chip working as a switching element, a terminal electrically coupled with the semiconductor chip and the wiring, a molded resin sealing the semiconductor chip and the terminal, and a heat radiation plate having a surface exposed from the molded resin and transferring heat generated at the semiconductor chip. The heat storage body has a heat capacity required to store the heat generated at the semiconductor chip. The heat storage body is coupled with the heat radiation plate. The insulator is in contact with the heat storage body or the semiconductor module. The heat sink is in contact with the insulator.

### CROSS REFERENCE TO RELATED APPLICATIONS

The present application is based on and claims priority to Japanese Patent Application No. 2011-138247 filed on Jun. 22, 2011, the contents of which are incorporated in their entirety herein by reference.

### TECHNICAL FIELD

The present disclosure relates to an electronic control unit.

### BACKGROUND

Conventionally, an electronic control unit that performs drive control of a motor used for an electric power steering system (EPS) of a vehicle is known. The electronic control unit includes a metal-oxide semiconductor field-effect transistor (MOSFET) and supplies a drive current to the motor. In the EPS, when a driver operates a steering wheel while a vehicle travels at a low speed or a vehicle stops, a large current flows into the MOSFET in a short time, and the MOSFET generates heat in a short time. Thus, the amount of an electric current suppliable to the MOSFET in the electronic control unit is limited in accordance with a heat radiation performance of the MOSFET. In cases where the amount of an electric current suppliable to the MOSFET in the electronic control unit is limited to, for example, 33A, the electronic control unit can be applied to a light vehicle. However, it is difficult to apply the electronic control unit to a normal vehicle.

JP-A-2002-83912 (hereafter, referred to as a patent document No. 1) discloses that when a MOSFET is mounted on a first surface of a substrate made of material including resin, the number of attachment processes and a process cost can be reduced without using a metal substrate. In the invention disclosed in the patent document No. 1, a heat radiation path for transferring heat generated at the MOSFET to a heat sink is provided to increase the amount of electric current suppliable to the MOSFET. In the fifth to eleventh embodiments in the patent document No. 1 (FIG. 9 to FIG. 15 in the patent document No. 1), the substrate defines a VIA hole at a position where the MOSFET is located, and the VIA hole is filled with grease including silicone. On a second surface of the substrate on which the MOSFET is disposed, the heat sink is disposed through the grease. Accordingly, heat generated at the MOSFET is transferred to the heat sink through the via hole and the grease. In the third and fourth embodiments in the patent document No. 1 (FIG. 7 and FIG. 8 in the patent document No. 1), a first heat sink is disposed to the second surface of the substrate at a position where the MOSFET is located through the grease, and a second heat sink is provided on a surface of the MOSFET opposite from the substrate through the grease. Accordingly, heat generated at the MOSFET is transferred to the first heat sink and the second heat sink through the grease. In an invention disclosed in JP-A-2010-245174 (corresponding to US 2010/0254093 A1, hereafter referred to as a second patent document No. 2), a grease holding portion having a box shape is provided inside a case that houses a substrate therein. The grease holding portion is filled with a grease and a transistor mounted on a substrate is buried in the grease. Accordingly, heat generated at the transistor is transferred through the grease from the grease holding portion to the case.

In the inventions disclosed in the patent documents No. 1 and 2, a heat capacity of the grease is small. Thus, when a large current flows into the MOSFET or the transistor in a short time, the temperature of the MOSFET or the transistor may rapidly increase. In addition, in the inventions disclosed in the patent documents No. 1 and 2, the manufacturing cost may increase by using a lot of grease or providing a VIA hole.

### SUMMARY

It is an object of the present disclosure to provide an electronic control unit that can restrict an increase in a temperature of a semiconductor module.

According to an aspect of the present disclosure, an electronic control unit includes a substrate, a semiconductor module, a heat storage body, an insulator, and a heat sink. The substrate is made of material including resin. The substrate has a first surface and a second surface. The substrate includes a wiring and a land on at least one of the first surface and the second surface. The semiconductor module includes a semiconductor chip, a terminal, a molded resin, and a heat radiation plate. The semiconductor chip works as a switching element. The terminal is electrically coupled with the semiconductor chip and the wiring. The molded resin seals the semiconductor chip and the terminal. The heat radiation plate has a surface exposed from the molded resin and transfers heat generated at the semiconductor chip. The heat storage body is made of metal having a heat capacity required to store the heat generated at the semiconductor chip. The heat storage body is coupled with the heat radiation plate of the semiconductor module. The insulator is in contact with the heat storage body or the semiconductor module. The heat sink is in contact with the insulator. The heat sink transfers heat of the heat storage body and the semiconductor module.

The electronic control unit can restrict an increase in a temperature of the semiconductor module. Thus, the amount of electric current suppliable to the semiconductor module can be increased.

### BRIEF DESCRIPTION OF THE DRAWINGS

Additional objects and advantages of the present disclosure will be more readily apparent from the following detailed description when taken together with the accompanying drawings. In the drawings:

FIG. 1 is a cross-sectional view of a part of an electronic control unit according to a first embodiment of the present disclosure;

FIG. 2 is a diagram showing an electric power steering system including the electronic control unit according to the first embodiment;

FIG. 3 is a cross-sectional view of the electronic control unit according to the first embodiment from which a casing is removed;

FIG. 4 is a plan view of the electronic control unit viewed along the arrow IV in FIG. 3;

FIG. 5 is a partial cross-sectional view of the electronic control unit according to the first embodiment;

FIG. 6 is a plan view of the electronic control unit viewed along the arrow VI in FIG. 5;

FIG. 7 is a cross-sectional view of a part of an electronic control unit according to a second embodiment of the present disclosure;

FIG. 8A is a side view of a heat storage body of the electronic control unit according to the second embodiment and FIG. 8B is a plan view of the heat storage body viewed along the arrow VIIIB in FIG. 8A;

FIG. 9 is a cross-sectional view of the electronic control unit according to the second embodiment from which a casing is removed;

FIG. 10 is a plan view of the electronic control unit shown in FIG. 9;

FIG. 11 is a partial cross-sectional view of the electronic control unit according to the second embodiment;

FIG. 12 is a plan view of the electronic control unit shown in FIG. 11;

FIG. 13 is a cross-sectional view of a part of an electronic control unit according to a third embodiment of the present disclosure;

FIG. 14 is a cross-sectional view of a part of an electronic control unit according to a fourth embodiment of the present disclosure;

FIG. 15 is a cross-sectional view of the electronic control unit according to the fourth embodiment from which a casing is removed;

FIG. 16 is plan view of the electronic control unit viewed along the arrow XVI in FIG. 15;

FIG. 17 is a cross-sectional view of a part of an electronic control unit according to a fifth embodiment of the present disclosure;

FIG. 18 is a cross-sectional view of a part of an electronic control unit according to a sixth embodiment of the present disclosure;

FIG. 19 is a cross-sectional view of a part of an electronic control unit according to a seventh embodiment of the present disclosure;

FIG. 20 is a cross-sectional view of a part of an electronic control unit according to an eighth embodiment of the present disclosure;

FIG. 21 is a cross-sectional view of a part of an electronic control unit according to a ninth embodiment of the present disclosure;

FIG. 22 is a cross-sectional view of a part of an electronic control unit according to a tenth embodiment of the present disclosure;

FIG. 23 is a cross-sectional view of a part of an electronic control unit according to an eleventh embodiment of the present disclosure;

FIG. 24 is a cross-sectional view of a part of an electronic control unit according to a twelfth embodiment of the present disclosure;

FIG. 25 is a cross-sectional view of a part of an electronic control unit according to a thirteenth embodiment of the present disclosure; and

FIG. 26 is a partial cross-sectional view of the electronic control unit according to the thirteenth embodiment.

### DETAILED DESCRIPTION

### First Embodiment

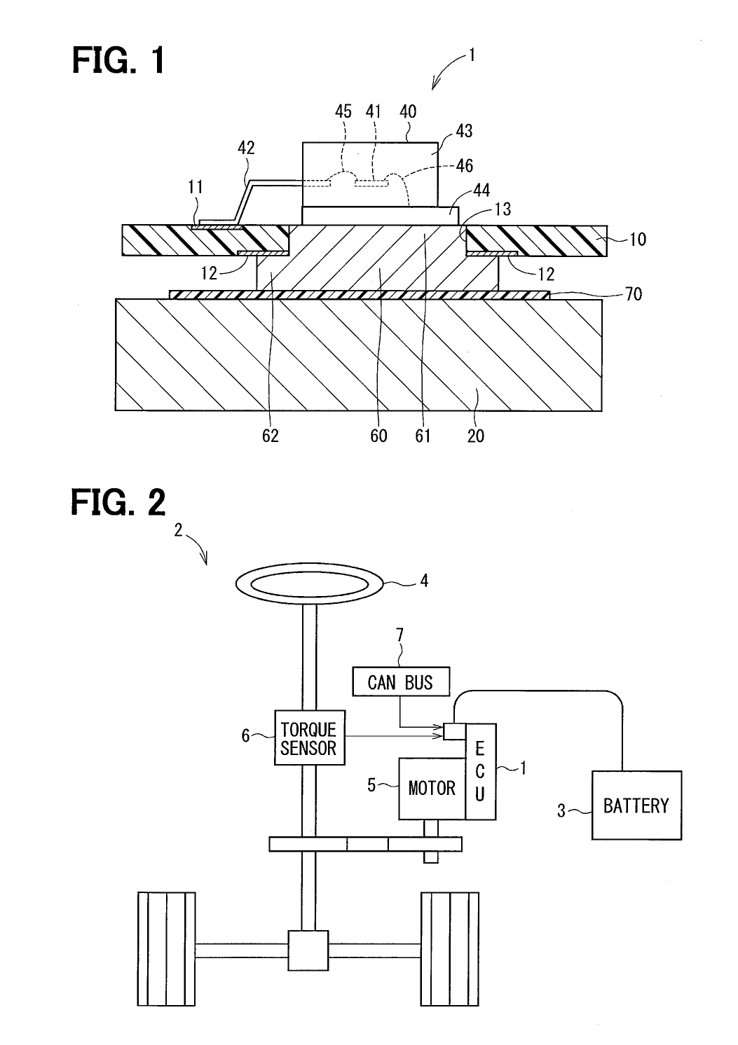

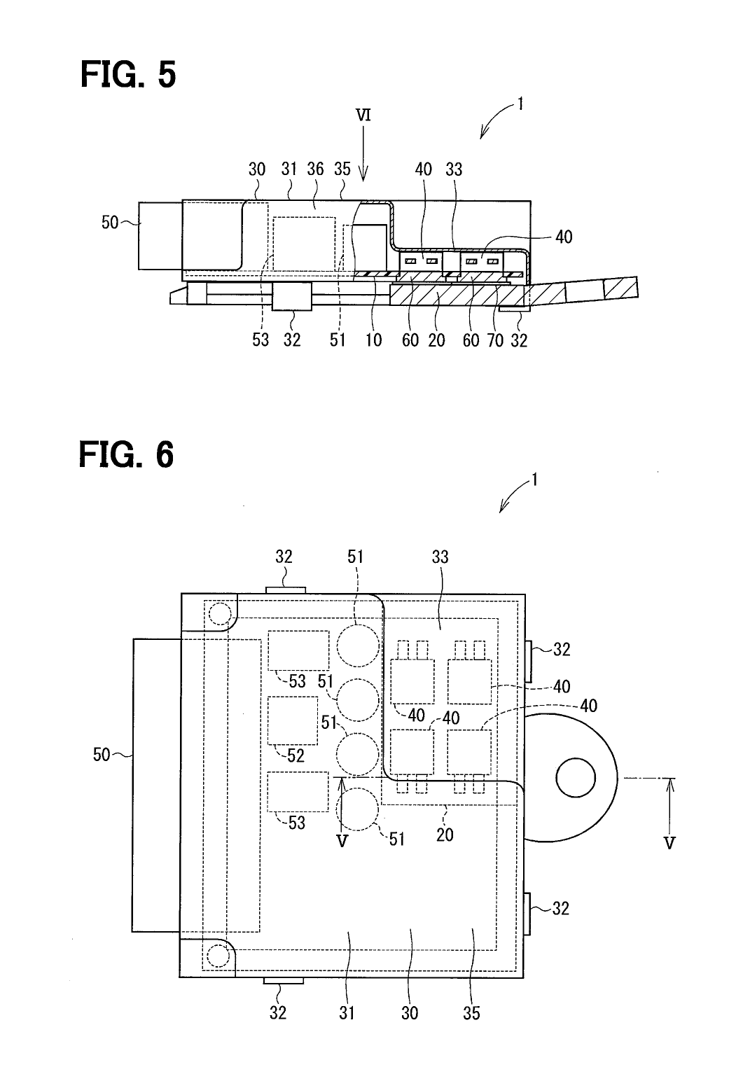

An electronic control unit 1 according to a first embodiment of the present disclosure will be described with reference to FIG. 1 to FIG. 6. As shown in FIG. 2, the electronic control unit 1 can be used for an electronic power steering system 2 of a vehicle. The electronic control unit 1 switches electric current supplied from the battery 2 to perform drive control of a motor 5 that generates an assist force of steering operation with a steering wheel 4.

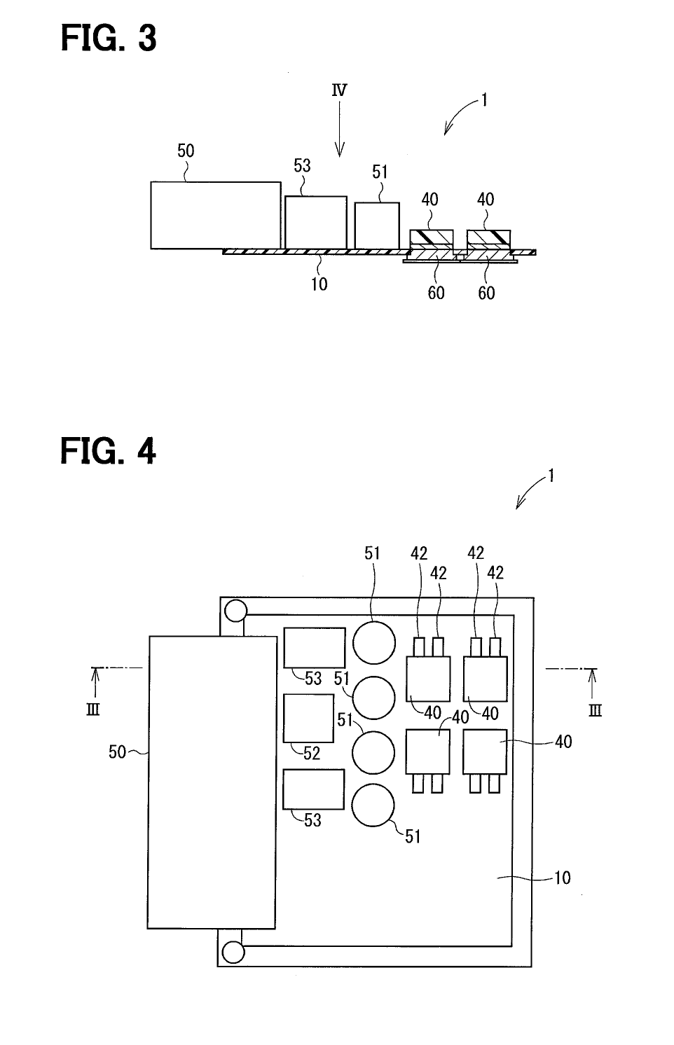

As shown in FIG. 3 to FIG. 6, the electronic control unit 1 includes a substrate 10, a heat sink 20, and a casing 30. On a surface of the substrate 10, multiple electronic components are mounted. The substrate 10 is fixed to the heat sink 20. The casing 30 is attached to the substrate 10 and the heat sink 20. The substrate 10 may be a printed wired board made of FR-4 that includes a glass woven fabric and epoxy resin. Four MOSFETs 40 as semiconductor modules are mounted on a surface of the substrate 10. The MOSFETs 40 may form an H-bridge circuit. The MOSFETs 40 switch electric current supplied from the battery 3 through a connector 50 to provide a drive current to the motor 5. A microcomputer (not shown) is also mounted on the substrate 10. The microcomputer calculates a rotation direction and a rotation torque of the motor 5 based on a steering torque signal transmitted from a torque sensor 6 and a vehicle speed signal transmitted from a control area network 7 to control a switching operation of each of the MOSFETs 40. The microcomputer monitors a temperature of each of the MOSFETs 40. On the substrate 10, capacitors 51, a coil 52, and relays 53 are also mounted. The capacitors 51 absorb a surge voltage generate due to the switching operation of the MOSFETs 40. The coil 52 reduces power supply noise signals. The relays 53 control energization when the temperature of the MOSFETs 40 is higher than a predetermined temperature.

As shown in FIG. 1, the substrate 10 includes wirings 11 and lands 12 made of metal thin films such as copper thin films. The substrate 10 defines a hole 13 having a cylindrical shape. The hole 13 penetrates the substrate 10 from a first surface to a second surface. Each of the MOSFET 40 includes a semiconductor chip 41, two terminals 42, a molded resin 43, and a heat radiation plate 44. The semiconductor chip 41 works as a switching element and is formed on a p-type or n-type silicon substrate. The molded resin 43 has an approximately rectangular parallelepiped shape. The molded resin 43 seals the semiconductor chip 41 to protect the semiconductor chip 41 against impact and moisture. An end of one of the terminals 42 is electrically coupled with a source of the semiconductor chip 41 through a bonding wire 45 in the molded resin 43. The other end of the one of the terminals 42 protrudes from the molded resin 43. An end of the other terminal 42 is electrically coupled with a gate of the semiconductor chip 41 through a bonding wire in the molded resin 43 and the other end of the other terminal 42 protrudes from the molded resin 43. The heat radiation plate 44 has an approximately rectangular parallelepiped shape and is made of, for example, copper. One surface of the heat radiation plate 44 Is coupled with the molded resin 43, and the other surface of the heat radiation plate 44 is exposed outside from the molded resin 43. Heat generate at the semiconductor chip 41 is transferred to the heat radiation plate 44. The heat radiation plate 44 is electrically coupled with a drain of the semiconductor chip 41 through a bonding wire 46 in the semiconductor chip 41. The two terminals 42 are electrically coupled with the wirings 11 on the first surface of the substrate 10 by soldering.

A heat storage body 60 is made of, for example, copper. The heat storage body 60 includes an inserted section 61 and a heat transmission section 62 that are integrated. The inserted section 61 has a cylindrical shape and the heat transmission section 62 has a rectangular parallelepiped shape. The inserted section 61 is inserted into the hole 13 of the substrate 10 and is joined with the heat radiation plate 44 of the MOSFET 40 by soldering. A diameter of the inserted section 61 is longer than a diagonal line of the heat radiation plate 44. Thus, an area of a surface of the inserted section 61 facing the heat radiation plate 44 is larger than an area of a surface of the heat radiation plate 44 facing the inserted section 61. The heat transmission section 62 extends from the inserted section 61 in a direction from the first surface to the second surface. The heat transmission section 62 is joined with the lands 12 on the second surface of the substrate 10 by soldering. The heat transmission section 62 is larger than the inserted section 61 in a planar direction of the substrate 10, that is, an extending direction of the substrate 10. Thus, an area of a surface of the heat transmission section 62 facing the heat sink 20 is larger than an area of a surface of the inserted section 61 facing the heat radiation plate 44. The heat storage body 60 has a heat capacity required to (enough to) store heat generated from the semiconductor chip 41 when a large current flows into the semiconductor chip 41 in a predetermined time. The heat storage body 60 transfers heat generated at the semiconductor chip 41 to the heat sink 20 through an insulation sheet 70.

The insulation sheet 70, which can operate as an insulator, is disposed on the surface of the heat storage body 60 facing the heat sink 20. The insulation sheet 70 may be an insulation heat radiation sheet including silicone and having a small resistance. As the insulator, heat radiation grease including silicone as base material and the insulation sheet 70 may be used in combination. The heat sink 20 may be made of aluminum. The heat sink 20 is disposed on an opposite surface of the insulation sheet 70 from the heat storage body 60. The heat sink 20 has a heat capacity required to (enough to) store heat transferred from the heat storage body 60. The heat sink 20 radiates the heat to outside air. When a heat generation amount is small, the heat sink 20 and the insulation sheet 70 can be omitted.

As shown in FIG. 5, the four MOSFETs 40 are arranged on the substrate in an approximately quadrangular manner. The casing 30 includes a casing body 31, four lugs 32 and a pressing section 33. The casing 30 covers the substrate 10, the MOSFETs 40, the heat storage body 60, the insulation sheet 70, and the heat sink 20. The casing body 31 includes an upper surface 35 and a side surface 36. Each of the lugs 32 has an approximately L shape extending from the side surface 36 of the casing body 31 to a rear surface of the heat sink 20 and is swaged to the rear surface of the heat sink 20. The pressing section 33 protrudes from the upper surface 35 of the casing body 31 toward the MOSFETs 40. When the lugs 32 are swaged to the heat sink 20, the pressing section 33 presses the MOSFETs 40 toward the heat sink 20. Accordingly, the heat storage body 60, the insulation sheet 70, and heat sink 20 are adhered each other and the insulation sheet 70 is compressed.

A manufacturing method of the electronic control unit 1 will be described. Firstly, a solder paste is applied to the lands 12 on the second surface of the substrate 10. Then, the heat storage body 60 is inserted into the hole 13 of the substrate 10 to fit the heat storage body 60 to the lands 12. After heated in a reflow furnace, the substrate 10 and the heat storage body 60 are cooled. Accordingly, the heat storage body 60 is mounted on the substrate 10.

Next, a solder paste is applied to the wiring 11 on the first surface of the substrate 10 and an end surface of the heat storage body 60 facing to the first surface side of the substrate 10. The heat radiation plates 44 of the MOSFETs 40 are mounted on the end surface of the heat storage body 60 facing to the first surface side of the substrate 10. The terminals 42 of the MOSFETs 40, the capacitors 51, the relays 53, and the connector 50 are disposed on the wiring 11 on the first surface of the substrate 10. After heated in a reflow furnace, the substrate 10 and the like are cooled. Accordingly, the electronic components are mounted on the substrate 10. The substrate 10 is disposed on the heat sink 20 through the insulation sheet 70. Then, the substrate 10 is covered with the casing 30, and the lugs 32 of the casing 30 are swaged to the heat sink 20. Accordingly, the electronic control unit 1 is completed.

The electronic control unit 1 according to the present embodiment has the following effects as examples.

In the present embodiment, heat generated at the MOSFETs 40 is directly transferred from the heat radiation plate 44 to the heat storage body 60. Thus, in cases where a driver operates the steering wheel 4 while the vehicle travels at a low speed or the vehicle stops, and a large current flows into the MOSFETs 40 in a short time, the heat ration plate 44 and the heat storage body 60 store heat, and an increase in the temperature of the MOSFETs 40 can be restricted. Thus, the amount of electric current suppliable to the MOSFETs 40 can be increased. In cases where electric current intermittently flow into the MOSFETs for a long time while the vehicle travels, heat is transferred from the heat storage body 60 to the heat sink 20 through the insulation sheet 70. Because an area of a surface from which heat is radiated increased, an increase in the temperature of the MOSFETs 40 can be restricted. Thus, a large current can be supplied in a short time while using the MOSFETs 40 having small heat radiation plates 44. As a result, a manufacturing cost of the electronic control unit 1 used for the electronic power steering system 2 can be reduced.

In the present embodiment, the heat storage body 60 is disposed from an inside of the hole 13 of the substrate 10 to the second surface side of the substrate 10. Accordingly, a region, in which the electronic components other than the MOSFETS can be disposed, can be secured over a wide area in the substrate 10. Thus, a freedom of design can be increased.

In the present embodiment, the area of the surface of inserted section 61 facing the heat radiation plate 44 is larger than the area of the surface of the heat radiation plate 44 facing the inserted section 61. Accordingly, a thermal resistance from the heat radiation plate 44 to the heat storage body 60 can be small. Thus, when electric current flows into the MOSFETs 40, the increase in the temperature of the MOSFETs 40 can be restricted.

In the present embodiment, the area of the surface of the heat transmission section 62 facing the heat sink 20 is larger than the area of the surface of the inserted section 61 facing the heat radiation plate 44. Thus, a thermal resistance from the heat storage body 60 to the heat sink 20 can be small, and heat is easily transferred. Therefore, when electric current intermittently flows into the MOSFETs 40 for a long time, the increase in the temperature of the MOSFETs 40 can be restricted.

In the present embodiment, the pressing section 33 of the casing 30 presses the MOSFETs 40 toward the heat sink 20 so that the heat storage body 60, the insulation sheet 70, and the heat sink 20 are adhered to each other and the insulation sheet 70 is compressed. Accordingly, a distance between the heat storage body 60 and the heat sink 20 can be reduced, and a thermal resistance between the heat storage body 60 and the heat sink 20 can be small.

### Second Embodiment

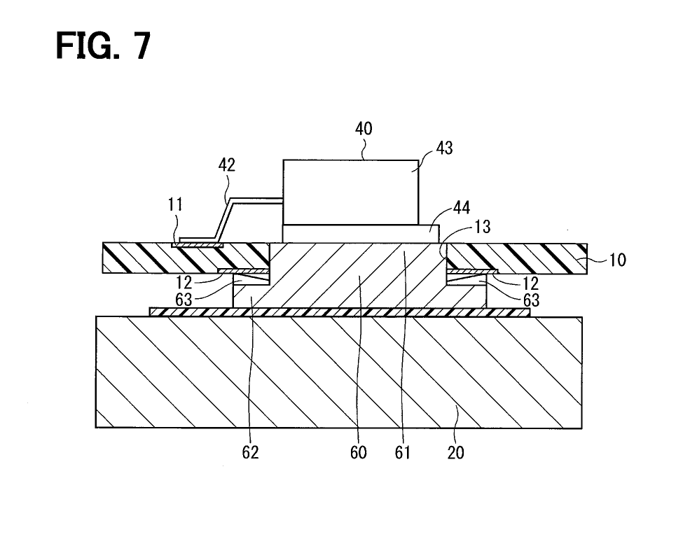

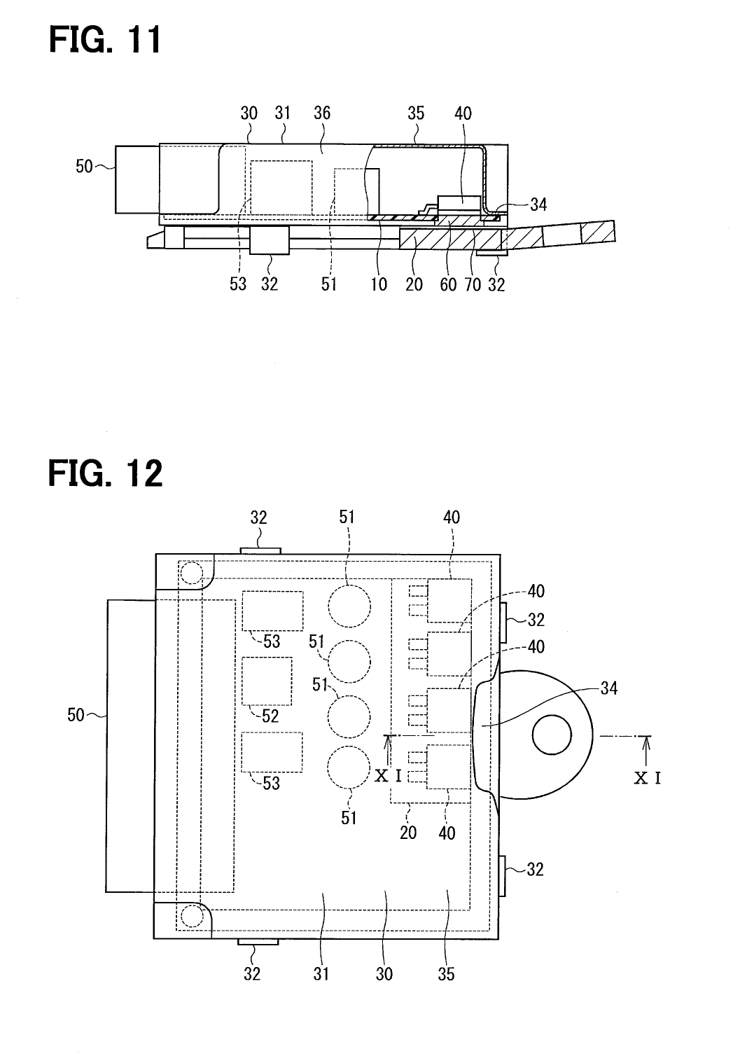

An electronic control unit 1 according to a second embodiment of the present disclosure will be described with reference to FIG. 7 to FIG. 12. In the present embodiment, components substantially similar to the above-described components of the first embodiment are denoted by the same reference numerals.

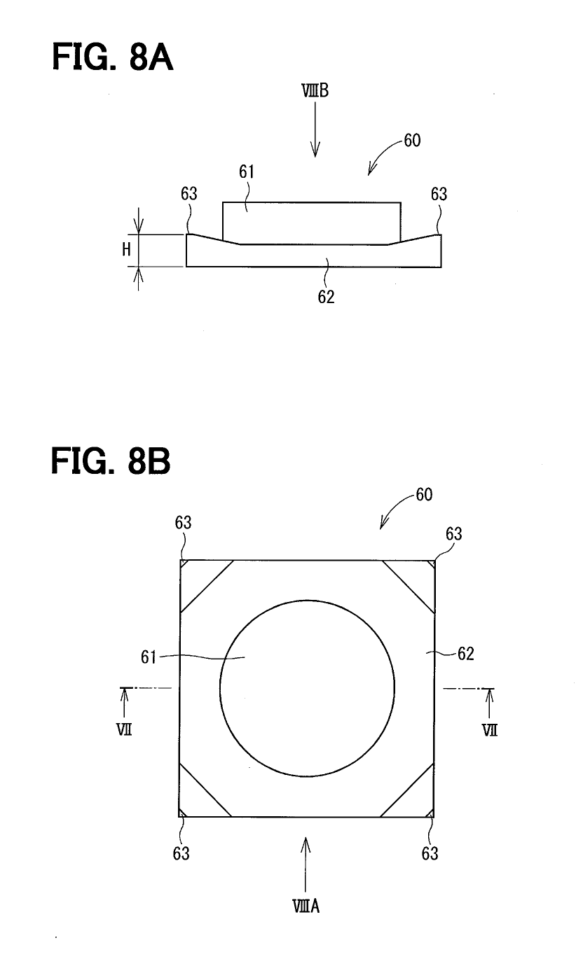

In the present embodiment, as shown in FIG. 7, FIG. 8A, and FIG. 8B, a heat storage body 60 includes contact sections 63 at respective corners of a heat transmission section 62. The contact sections 63 extend from the heat transmission section 62 toward a substrate 10. The heat storage body 60 includes the contact sections 63, the heat transmission section 62, and an inserted section 61 which are integrated. The heat storage body 60 is formed such that a distance H between an end surface of the contact sections 63 facing the substrate 10 and an end surface of the heat transmission section 62 facing the heat sink 20 is accurate. In a cross section parallel to the substrate 10, a dimension of the contact sections 63 decreases from an end adjacent to the heat transmission section 62 to an end adjacent to the substrate 10. Thus, an area of joined surfaces of the contact sections 63 joined with lands 12 on a second surface of the substrate 10 is smaller than an area of a surface of the heat transmission section 62 facing the substrate 10. The contact sections 63 are solder to the lands 12 on the second surface of the substrate 10. When the contact sections 63 are come into contact with the lands 12 to which a cream solder is applied, the lands 12 and the contact sections 63 can be easily joined each other with a small pressing force. Thus, when multiple heat storage bodies 60 are mounted on the substrate 10, ends of the heat storage bodies 60 adjacent to the heat sink 20 can be arranged on the same plane.

In the present embodiment, because the area of the joined surfaces of the contact sections 63 joined with the lands 12 on the second surface of the substrate 10 is smaller than the area of the surface of the heat transmission section 62 facing the substrate 10, the distance H of the heat storage body 60 can be easily and accurately set. Accordingly, when multiple heat storage bodies 60 are mounted on the substrate 10, ends of the heat storage bodies 60 adjacent to the heat sink 20 can be arranged on the same plane. Thus, distances between the multiple heat storage bodies 60 and the heat sink 20 do not vary, and thermal resistances between the heat storage bodies 60 and the heat sink 20 can be small.

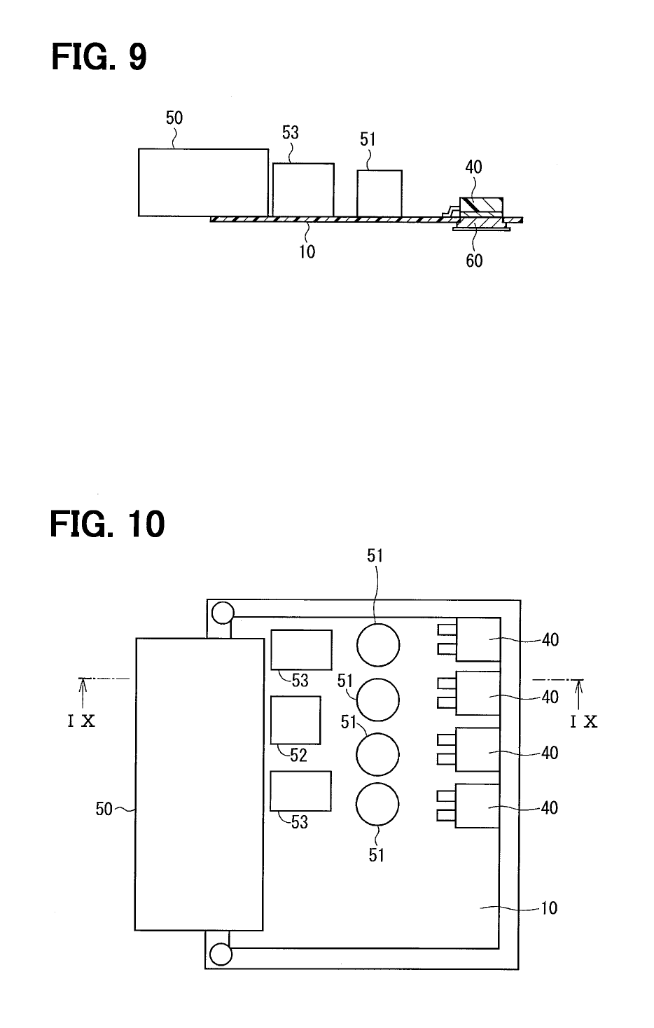

As shown in FIG. 9 to FIG, 12, multiple MOSFETs 40 are arranged in a line at an edge portion of substrate 10. A pressing section 34 of a casing 30 protrudes from an upper surface 35 of a casing body 31 toward the edge portion of the substrate 10. In other words, the pressing section 34 is disposed on the side surface 36 of the casing body 31 and presses the edge portion of the substrate 10. When lugs 32 of the casing 30 are swaged to the heat sink 20, the pressing section 34 presses the edge portion of the substrate 10 toward the heat sink 20. Accordingly, the heat storage body 60, an insulation sheet 70, and heat sink 20 are adhered each other and the insulation sheet 70 is compressed. Accordingly, the distance between the heat storage bodies 60 and the heat sink 20 can be reduced, and the thermal resistances between the heat storage body 60 and the heat sink 20 can be small. Furthermore, because the pressing section 34 is disposed adjacent to a side surface of the casing body 31, a force generated by swaging the lugs 32 can effectively work to the pressing section 34. Accordingly, the pressing section 34 can press the insulation sheet 70 toward the heat sink 20 through the substrate 10.

### Third Embodiment

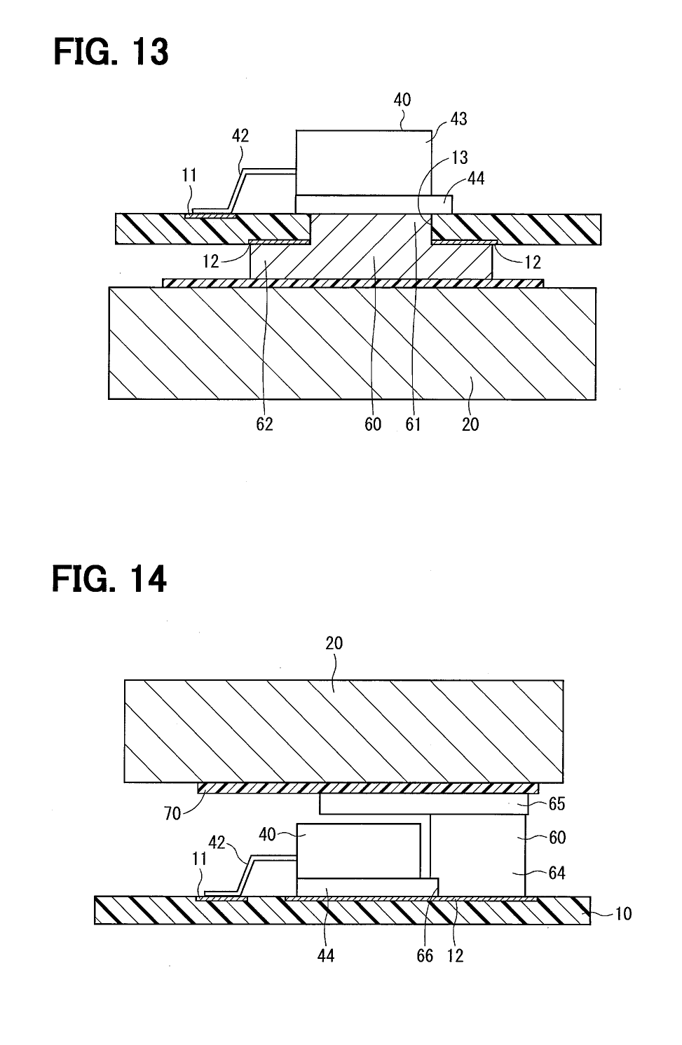

An electronic control unit 1 according to a third embodiment of the present disclosure will be described with reference to FIG. 13. In the present embodiment, an area of a surface of an inserted section 61 facing a heat radiation plate 44 is smaller than an area of a surface of the heat radiation plate 44 facing the inserted section 61. The inserted section 61 and the heat radiation plate 44 are joined with each other by soldering. Also in the present embodiment, when a large current flows into a MOSFET 40 in a short time, the heat radiation plate 44 and a heat storage body 60 store heat, and an increase in the temperature of the MOSFET 40 can be restricted. When an electric current intermittently flow into the MOSFET 40 for a long time, heat is transferred from the heat storage body 60 to a heat sink 20 through an insulation sheet 70. Thus, an increase in the temperature of the MOSFET 40 can be restricted. In the present embodiment, because the area of the surface of the inserted section 61 facing the heat radiation plate 44 is reduced, and an area of a region of a first surface of a substrate 10, in which electronic components other than the MOSFET 40 can be disposed, can be increased.

### Fourth Embodiment

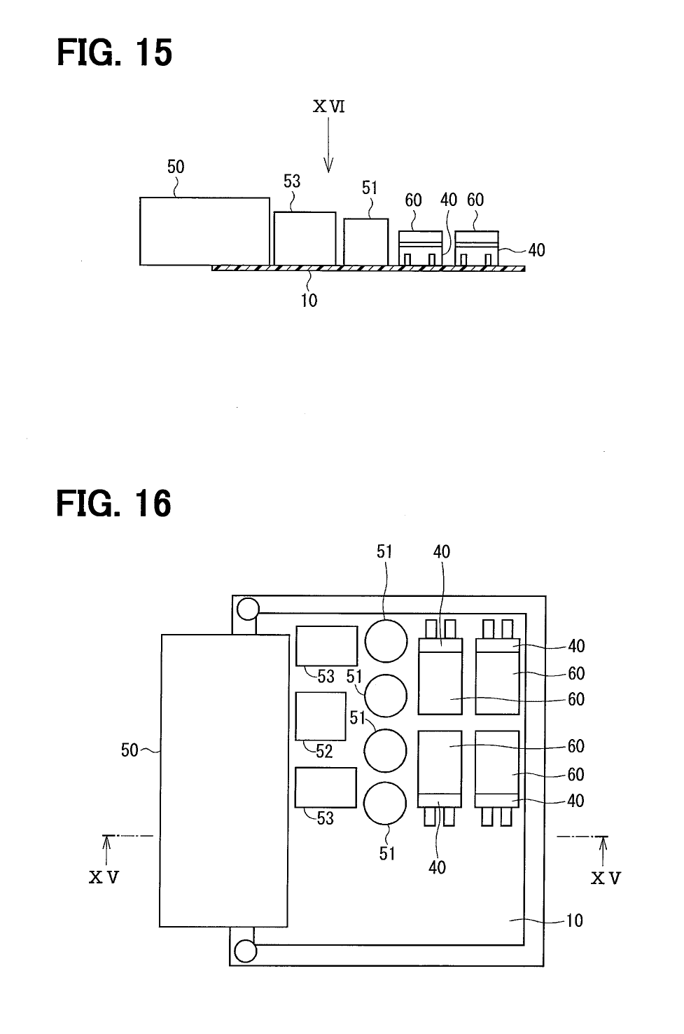

An electronic control unit 1 according to a fourth embodiment of the present disclosure will be described with reference to FIG. 14 to FIG. 16. In the present embodiment, as shown in FIG. 14, a heat radiation plate 44 of a MOSFET 40 and a heat storage body 60 are joined with the same land 12 on a first surface of a substrate 10 by soldering. The heat storage body 60 includes a connection section 64 coupled with the land 12 on the first surface of the substrate 10 and an extension section 65 extending in approximately parallel with the substrate 10 on an opposite side of the connection section 64 from the substrate 10. The connection section 64 has a depressed section 66 at a portion adjacent to the substrate 10. The depressed section 66 is depressed in an opposite direction from the substrate 10. The heat radiation plate 44 of the MOSFET 40 is in contact with the depressed section 66 of the connection section 64. On an opposite side of the extension section 65 from the substrate 10, and insulation sheet 70 is disposed. A heat sink 20 is disposed on an opposite side of the insulation sheet 70 opposite from the heat storage body 60. The heat sink 20 radiates the heat to outside air. As shown in FIG. 15 and FIG. 16, four MOSFETs 40 are arranged on the substrate in an approximately quadrangular manner. On the substrate 10, capacitors 51, a coil 52, relays 53, and a connector 50 are also mounted.

In the present embodiment, heat generated at the MOSFET 40 is transferred from the heat radiation plate 44 to the heat storage body 60 through the land 12. Furthermore, heat is directly transferred from the heat radiation plate 44 to the depressed section 66 of the heat storage body 60. Thus, when a large current flows into the MOSFET 40 in a short time, the heat storage body 60 stores heat, and an increase in a temperature of the MOSFET 40 can be restricted. In the present embodiment, an area of a surface of the extension section 65 facing the heat sink 20 is larger than an area of a surface of the connection section 64 facing the land 12. Thus, heat is easily transferred from the heat storage body 60 to the heat sink 20. Thus, when an electric current intermittently flows into the MOSFET 40, an increase in the temperature of the MOSFET 40 can be restricted.

### Fifth Embodiment

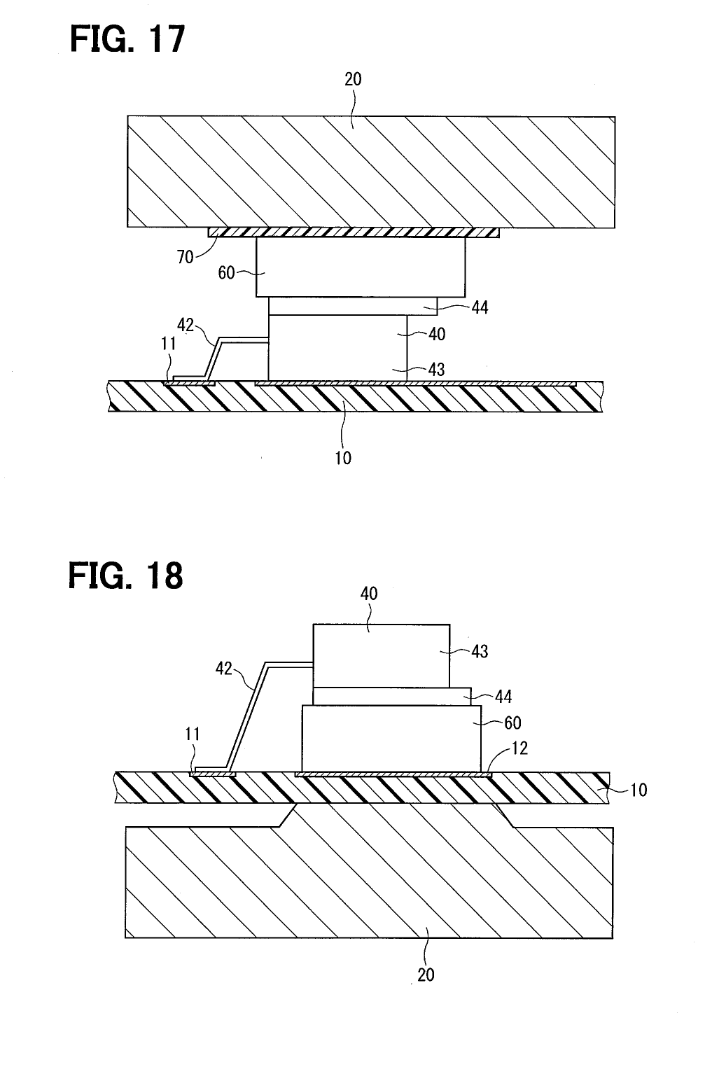

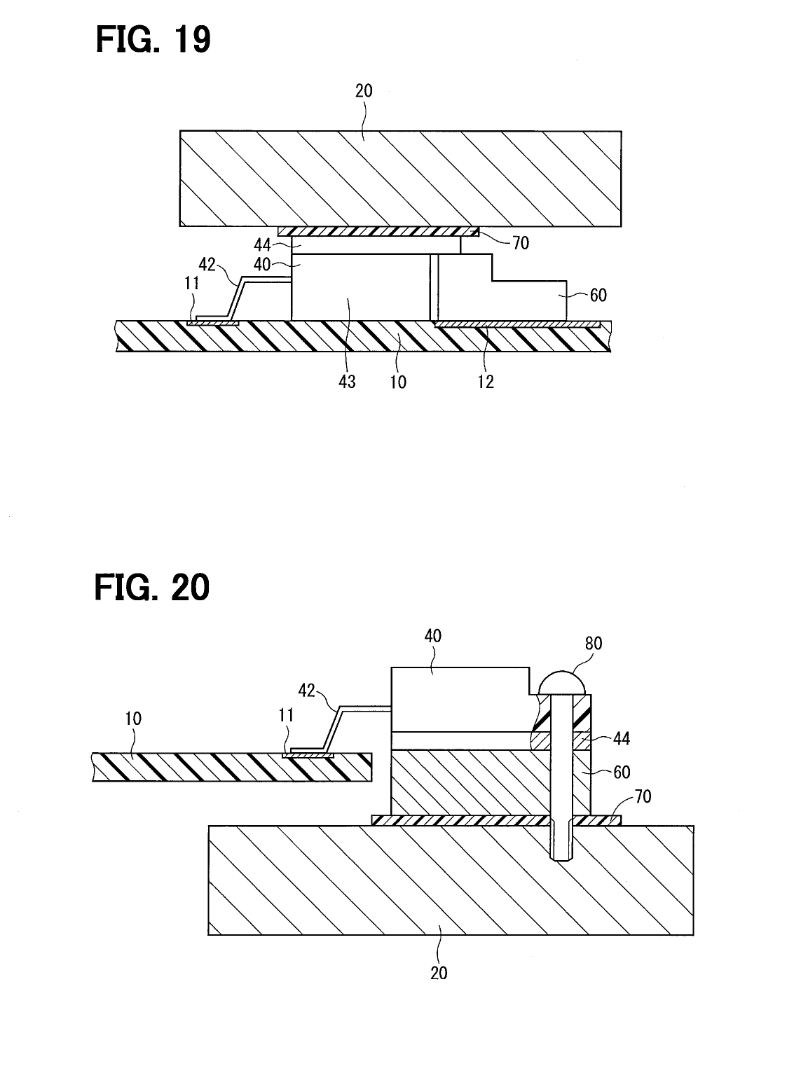

An electronic control unit 1 according to a fifth embodiment of the present disclosure will be described with reference to FIG. 17. In a present embodiment, a MOSFET 40 is in contact with a substrate 10, and a heat radiation plate 44 is disposed on an opposite side of the MOSFET 40 from the substrate 10. A heat storage body 60 is joined with the heat radiation plate 44 of the MOSFET 40 by soldering. A heat storage body 60 is larger than the heat radiation plate 44. The heat storage body 60 has a heat capacity required to (enough to) store heat generated at the MOSFET 40 when a large current flows into the MOSFET 40 in a predetermined time. On an opposite side of the heat storage body 60 from the MOSFET 40, a heat sink 20 is disposed through an insulation sheet 70. The heat sink 20 stores heat transferred from the heat storage body 60 and radiates the heat to outside air.

In the present embodiment, a large current can be supplied to the MOSFET 40 having the small heat radiation plate 44 without providing a hole in the substrate 10. Thus, a manufacturing cost of the electronic control unit 1 used for the electronic power steering system 2 can be reduced. In the present embodiment, because the heat storage body 60 is larger than the heat radiation plate 44, heat is easily transferred from the heat radiation plate 44 to the heat storage body 60. Furthermore, heat is easily transferred from the heat storage body 60 to the heat sink 20.

### Sixth Embodiment

An electronic control unit 1 according to a sixth embodiment of the present disclosure will be described with reference to FIG. 18. In the present embodiment, a heat storage body 60 is joined with a land 12 on a first surface of a substrate 10 by soldering. A heat radiation plate 44 of a MOSFET 40 is joined with an opposite side of the heat storage body 60 from the substrate 10 by soldering. Terminals 42 of the MOSFET extend to the substrate 10 and are joined with wirings 11 on the substrate 10 by soldering. The heat storage body 60 has a heat capacity required to (enough to) store heat generated at the MOSFET when a large current flows into the MOSFET 40 in a short time. A heat sink 20 is disposed to an opposite side of the heat storage body 60 from the MOSFET 40 through the substrate 10. In the present embodiment, the substrate 10 between the heat storage body 60 and the heat sink 20 can work as an insulator. The heat sink 20 stores heat transferred from the heat storage body 60 and radiates heat to outside air.

### Seventh Embodiment

An electronic control unit 1 according to a seventh embodiment of the present disclosure will be described with reference to FIG. 7. In the present embodiment, a molded resin 43 of a MOSFET 40 is in contact with a substrate 10, and a heat radiation plate 44 of the MOSFET 40 is disposed on an opposite side from the substrate 10. A heat storage body 60 is joined with a land 12 on the substrate 10 by soldering. An end surface of the heat storage body 60 opposite from the substrate 10 is in contact with the heat radiation plate 44. Accordingly, heat generated at the MOSFET 40 is transferred from the heat radiation plate 44 to the heat storage body 60. The heat storage body 60 has a heat capacity required to (enough to) store heat generated at the MOSFET 40 when a large current flows into the MOSFET 40 in a short time. On a surface of the heat radiation plate 44 of the MOSFET 40, a heat sink 20 is disposed through an insulation sheet 70. The heat sink 20 stores heat transferred from the heat radiation plate 44 and radiates the heat to outside air.

### Eighth Embodiment

An electronic control unit 1 according to an eighth embodiment of the present disclosure will be described with reference to FIG. 20. In the present embodiment, an insulation sheet 70, a heat storage body 60, and a MOSFET 40 are attached to a heat sink 20 with a screw 80. A heat radiation plate 44 of the MOSFET 40 is joined with an opposite side of the heat storage body 60 from the heat sink 20 by soldering. Terminals of the MOSFET 40 are joined with the wirings of the substrate 10 by soldering. The heat sink 20 is away from the substrate 10. The heat storage body 60 has a heat capacity required to (enough to) store heat generated at the MOSFET 40 when a large current flows into the MOSFET 40 in a short time. The heat sink 20 stores heat transferred from the heat storage body 60 and radiates the heat to outside air. Furthermore, heat generated at the MOSFET 40 is transferred from the heat storage body 60 to the heat sink 20 through the screw 80. Thus, a thermal resistance between the heat storage body 60 and the heat sink 20 can be small, and heat is easily transferred. In the present embodiment, the heat sink 20 may be made of a metal substrate.

### Ninth Embodiment

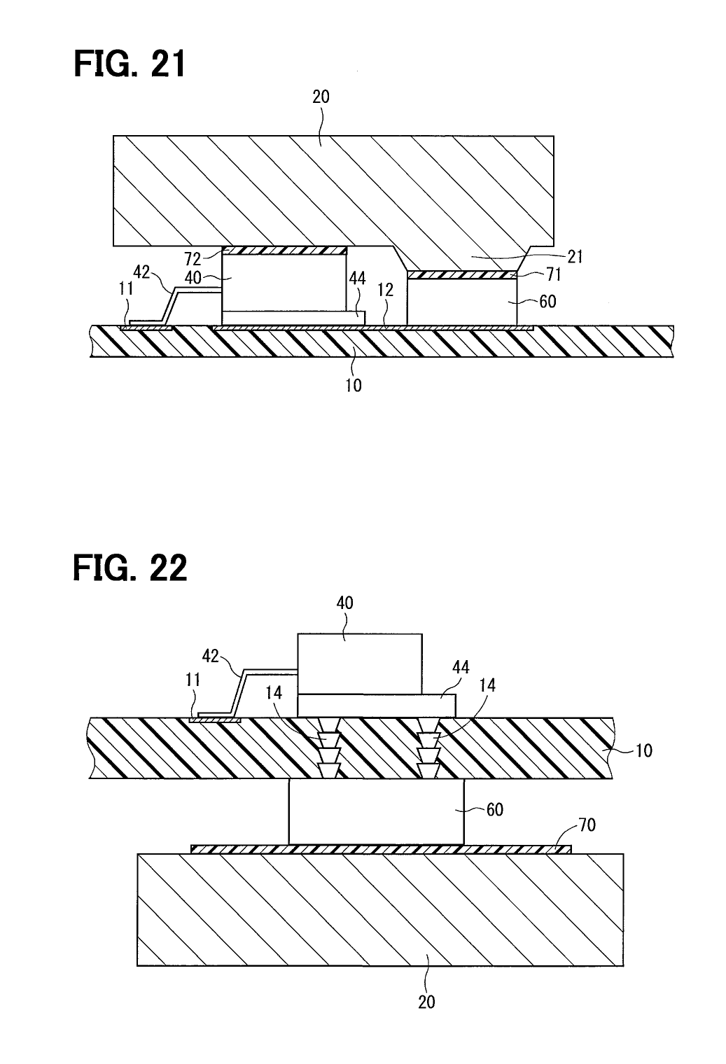

An electronic control unit 1 according to a ninth embodiment of the present disclosure will be described with reference to FIG. 21. In the present embodiment, a heat radiation plate 44 of a MOSFET 40 and a heat storage body 60 are joined with the same land 12 on a substrate 10 by soldering. On an opposite side of the heat storage body 60 from the substrate 10, a fist insulation sheet 71 is disposed. In addition, on an opposite side of the MOSFET 40 from the substrate 10, a second insulation sheet 72 is provided. The heat sink 20 includes a protruding section 21 that protrudes toward the heat storage body 60. The heat sink 20 is disposed on the opposite side of the heat storage body 60 and the MOSFET 40 from the substrate 10 through the first insulation sheet 71 and the second insulation sheet 72.

In the present embodiment, heat generated at the MOSFET 40 is transferred from the heat radiation plate 44 to the heat storage body 60 through the land 12. Thus, when a large current flows into the MOSFET 40 in a short time, the heat storage body 60 stores heat, and an increase in a temperature of the MOSFET 40 can be restricted. Heat of the heat storage body 60 is transferred to the heat sink 20 through the first insulation sheet 71. Heat generated at the MOSFET is transferred from a molded resin 43 to the heat sink 20 through the second insulation sheet 72. Thus, a heat radiation property of the MOSFET 40 can be increased.

### Tenth Embodiment

An electronic control unit 1 according to a tenth embodiment of the present disclosure will be described with reference to FIG. 22. In the present embodiment, wirings 14 are formed in a thickness direction of a substrate by a buildup method. The wirings 14 are formed by filling a hole defined by the substrate 10 in the thickness direction with copper plating. The wirings 14 are formed in a portion of the substrate 10 on which the MOSFET 40 is mounted. A heat radiation plate 44 of the MOSFET 40 is joined with ends of the wirings 14 exposed from a first surface of the substrate 10 by soldering. A heat storage body 60 is joined with ends of the wirings 14 exposed from a second surface of the substrate 10 by soldering. In the present embodiment, heat generated at the MOSFET 40 is transferred from the heat radiation plate 44 to the heat storage body 60 through the wirings 14 that extend in the thickness direction of the substrate 10. The heat storage body 60 has a heat capacity required to (enough to) store heat generated at the MOSFET 40 when a large current flows into the MOSFET 40 in a short time. Heat of the heat storage body 60 is transferred to the heat sink 20 through an insulation sheet 70.

### Eleventh Embodiment

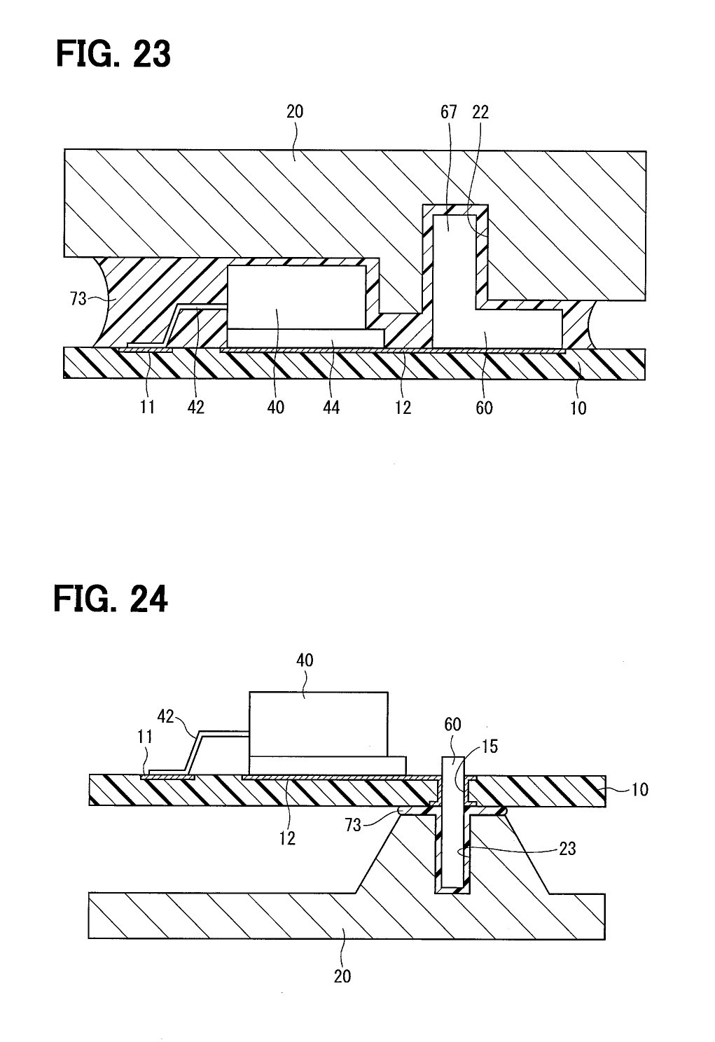

An electronic control unit 1 according to an eleventh embodiment of the present disclosure will be described with reference to FIG. 23. In the present embodiment, a heat radiation plate 44 of a MOSFET 40 and a heat storage body 60 are joined with the same land 12 on a first surface of a substrate 10 by soldering. The heat storage body 60 includes a protruding section 67 that protrudes in an opposite direction from the substrate 10. A heat sink 20 has a groove 22 corresponding to the protruding section 67 of the heat storage body 60. A space between the heat sink 20 and the substrate 10, the MOSFET 40, and the heat storage body 60 is filled with a heat radiation grease 73. In the present embodiment, an area of a surface of the heat storage body 60 facing the heat sink 20 is large. Thus, heat is easily transferred from the heat storage body 60 to the heat sink 20. In addition, because the heat radiation grease 73 reduces a thermal resistance between the heat sink 20 and the MOSFET 40 and the heat storage body 60, a heat radiation property of the MOSFET 40 can be increased. In the present embodiment, the heat storage body 60 may also have a depressed section that is depressed toward the substrate 10. In this case, the heat sink 20 may have a protruding section corresponding to the depressed section of the heat storage body 60.

### Twelfth Embodiment

An electronic control unit 1 according to a twelfth embodiment of the present disclosure will be described with reference to FIG. 24. In the present embodiment, a heat storage body 60 has a rod shape. The heat storage body 60 is fitted in a VIA hole 15 defined by a substrate 10 and protrudes from a second surface of the substrate 10. The heat storage body 60 is joined with the VIA hole 15 by soldering, and a MOSFET 40 is joined with a land 12 by soldering. The VIA hole 15 and the land 12 are continuously formed. The heat sink 20 is disposed on a second surface side of the substrate 10 and defines a receiving hole 23 in which a portion of the heat storage body 60 protruding from the second surface is fitted. A space between an inner wall of the receiving hole 23 of the heat sink 20 and the heat storage body 60 is filled with a heat radiation grease 73. In the present embodiment, when a large current flows into a MOSFET 40 in a short time, the heat storage body 60 stores heat and restricts an increase in temperature of the MOSFET 40. When an electric current intermittently flows into the MOSFET 40 for a long time, heat is transferred from the heat storage body 60 to the heat sink, an increase in the temperature of the MOSFET 40 can be restricted.

### Thirteenth Embodiment

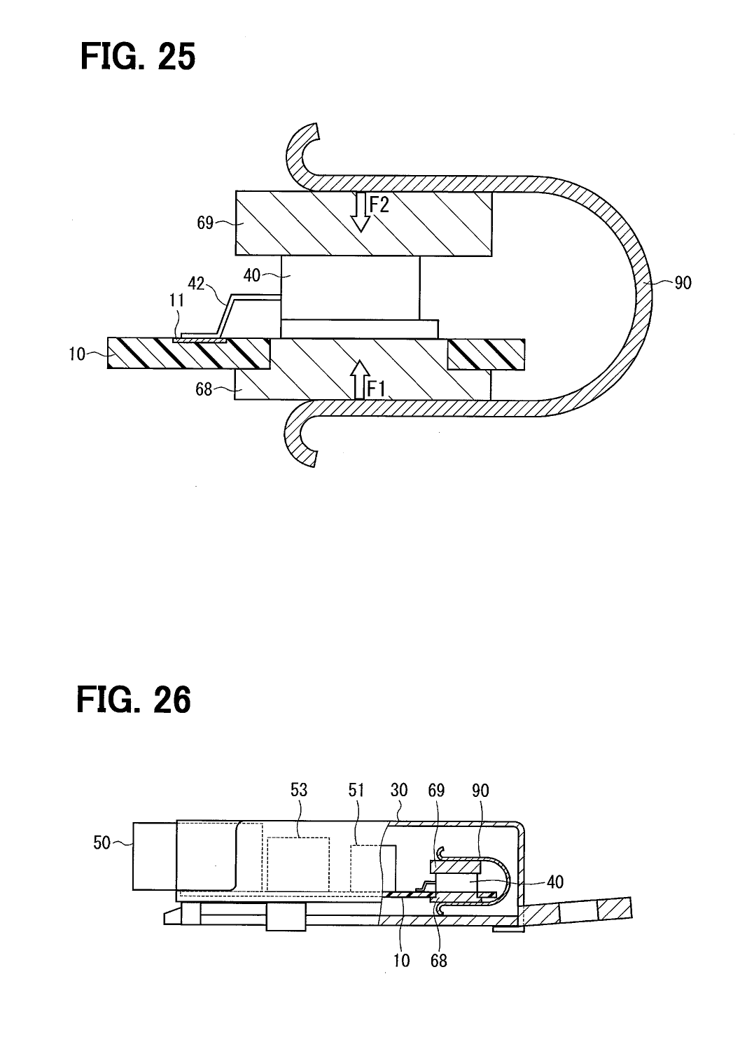

An electronic control unit 1 according to a thirteenth embodiment of the present disclosure will be described with reference to FIG. 25 and FIG. 26. In the present embodiment, as shown in FIG. 25, a first heat storage body 68 is disposed on a surface of a MOSFET 40 adjacent to a substrate 10. In addition, on a surface of the substrate 10 opposite from the MOSFET 40, a second heat storage body 69 is disposed. The first heat storage body 69 and the second heat storage body 69 are not soldered to the MOSFET 40. The first heat storage body 68, the second heat storage body 69, and the MOSFET 40 are held by a spring member 90 having an approximately U-shape in a cross section. As shown by the arrow F1 in FIG. 25, the spring member 90 presses the first heat storage body 68 toward the MOSFET 40 from below in a thickness direction of the substrate 10. In addition, as shown by the arrow F2 in FIG. 25, the spring member 90 presses the second heat storage body 69 toward the MOSFET 40 from above in thickness direction of the substrate 10. As shown in FIG. 26, the spring member 90 is disposed in a casing 30 with the substrate 10 and electronic components. In the present embodiment, the first heat storage body 68, the second heat storage body 69, and the MOSFET 40 can be fixed to each other without soldering.

### Other Embodiments

In each the above-described embodiments, the electronic control unit 1 for controlling the motor of the electric power steering system is described. An electronic control device according to another embodiment may be configured to control various motors.

In the above-described embodiments, the substrate 10 made of material including resin is made of FR-4 as an example. A substrate made of material including resin may also be a rigid substrate or a flexible substrate made of, for example, FR-5 or CEM-3.

In each the above-described embodiments, the electronic control unit 1 includes the MOSFET 40 as the semiconductor module. The semiconductor module may also be field effect transistor (FET), a Schottky barrier diode (SBD), or an insulated gate bipolar transistor (IGBT).

While the present disclosure has been described with reference to the foregoing embodiments, it is to be understood that the disclosure is not limited to the embodiments and constructions. The present disclosure is intended to cover various modification and equivalent arrangements.

What is claimed is:

1. An electronic control unit comprising:
a substrate made of material including resin, the substrate having a first surface and a second surface, the substrate including a wiring and a land on at least one of the first surface and the second surface;
a semiconductor module including a semiconductor chip, a terminal, a molded resin, and a heat radiation plate, the semiconductor chip working as a switching element, the terminal electrically coupled with the semiconductor chip and the wiring, the molded resin sealing the semiconductor chip and the terminal, the heat radiation plate having a surface exposed from the molded resin and transferring heat generated at the semiconductor chip;
a heat storage body made of metal having a heat capacity required to store the heat generated at the semiconductor chip, the heat storage body coupled with the heat radiation plate of the semiconductor module;
an insulator being in contact with the heat storage body or the semiconductor module; and
a heat sink being in contact with the insulator, the heat sink transferring heat of the heat storage body and the semiconductor module.

2. The electronic control unit according to claim 1, wherein
the heat storage body is in contact with the heat radiation plate of the semiconductor module.

3. The electronic control unit according to claim 1, wherein
the heat storage body and the heat radiation plate are joined with each other by soldering.

4. The electronic control unit according to claim 1, wherein
the substrate defines a hole that penetrates the substrate from the first surface to the second surface,
the heat storage body includes an inserted section and a heat transmission section,
the inserted section is fitted in the hole of the substrate and is joined with the heat radiation plate of the semiconductor module, and
the heat transmission section extends from the inserted section in a direction from the first surface to the second surface and is in contact with the insulator.

5. The electronic control unit according to claim 4, wherein
an area of a surface of heat transmission section facing the heat sink through the insulator is larger than an area of a surface of the inserted section facing the heat radiation plate.

6. The electronic control unit according to claim 4, wherein
the heat transmission section is larger than the inserted section in a direction parallel to a planar direction of the substrate.

7. The electronic control unit according to claim 4, wherein
an area of a surface of the inserted section facing the heat radiation plate is larger than an area of a surface of the heat radiation plate facing the inserted section.

8. The electronic control unit according to claim 4, wherein
the heat storage body further includes a contact section extending from the heat transmission section toward the substrate and joined with the land on the second surface of the substrate by soldering, and
an area of a joined surface of the contact section joined with the land is smaller than an area of a surface of the heat transmission section facing the substrate.

9. The electronic control unit according to claim 4, further comprising
a casing covering the substrate, the semiconductor module, the heat storage body, the insulator, and the heat sink, the casing including a casing body, a lug, and a pressing section, the casing body including an upper surface and a side surface, the lug extending from the side surface of the casing body and swaged to the heat sink, the pressing section pressing an end surface of the semiconductor module opposite from the heat sink or the first surface of the substrate in a state where the lug is swaged to the heat sink.

10. The electronic control unit according to claim 9, wherein
the semiconductor module is disposed at an edge portion of the substrate, and
the pressing section of the casing is disposed on the side surface of the casing body and presses the edge portion of the substrate at which the semiconductor module is disposed.

11. The electronic control unit according to claim 1, wherein
the heat radiation plate of the semiconductor module is in contact with the land on the first surface of the substrate, and
the heat storage body is in contact with the land on the first surface of the substrate so that the heat storage body is coupled with the heat radiation plate through the land.

12. The electronic control unit according to claim 11, wherein
the heat storage body and the heat radiation plate are joined with the land on the first surface of the substrate by soldering.

13. The electronic control unit according to claim 11, wherein
the heat storage body includes a protruding section that protrudes in an opposite direction from the substrate or a depressed section that is depressed toward the substrate, and
the heat sink has a shape corresponding to the protruding section or the depressed section of the heat storage body.

14. The electronic control unit according to claim 11, wherein
the heat storage body has a rod shape,
the heat storage body is fitted in a VIA hole defined by the substrate and protrudes from the second surface of the substrate, and
the heat sink has a receiving hole in which a portion of the heat storage body protruding from the second surface is fitted.

15. The electronic control unit according to claim 1, wherein
the wiring is formed in a thickness direction of the substrate by a buildup method, and
the heat radiation plate of the semiconductor module and the heat storage body are coupled with each other through the wiring.

16. The electronic control unit according to claim 1, further comprising a spring member, wherein
the heat radiation plate of the semiconductor module is in contact with the heat storage body in a thickness direction of the substrate,
the spring member presses the heat storage body toward the semiconductor module from one side in the thickness direction of the substrate, and
the spring member presses the semiconductor module toward the heat storage body from the other side in the thickness direction of the substrate.

17. The electronic control unit according to claim 1, further comprising a screw, wherein
the semiconductor module, the heat storage body, the insulator, and the heat sink are joined with each other by the screw.
